(19) United States
(12) Patent Application Publication
(10) Pub. No.: US 2011/0210769 A1
(43) Pub. Date: Sep. 1, 2011

(54) INTEGRATED CIRCUIT

(76) Inventor: Kee-Teok PARK, Gyeonggi-do (KR)

(21) Appl. No.: 12/982,717

(22) Filed: Dec. 30, 2010

(30) Foreign Application Priority Data
Feb. 26, 2010 (KR) 10-2010-0018114

(51) Int. Cl. H03L 7/00

(52) U.S. Cl. 327/142

(57) ABSTRACT

An integrated circuit includes a pad, an input buffer unit, and a supplementary driving unit. The pad is configured to receive a reset signal from an external device. The input buffer unit is configured to buffer a reset signal applied to the pad. The supplementary driving unit is configured to receive an output signal from the input buffer unit and supplementarily drive an input terminal of the input buffer unit to a deactivation level of the reset signal.

### CROSS-REFERENCE(S) TO RELATED APPLICATIONS

The present application claims priority of Korean Patent Application No. 10-2010-0018114, filed on Feb. 26, 2010, which is incorporated herein by reference in its entirety.

### BACKGROUND OF THE INVENTION

Exemplary embodiments of the present invention relate to semiconductor design technology, and more particularly, to integrated circuits.

A recent trend is to fabricate an integrated circuit such as a dynamic random access memory (DRAM) to have a low power consumption. Accordingly, the integrated circuit receives a reset signal from an external device. Herein, the reset signal is applied to initialize various internal circuits of the integrated circuit. Typically, the reset signal is a low active signal and is called a reset bar signal.

FIG. 1 is a block diagram of a known integrated circuit.

Referring to FIG. 1, an integrated circuit 100 includes a pad 110, an electrostatic discharge (ESD) protection unit 120, an input buffer unit 130, a first inverter INV1, and a second inverter INV2.

The pad 110 is configured to receive a reset signal RESETB from an external device.

The electrostatic discharge protection unit 120 is configured to discharge a static electricity of an abnormally high voltage applied to the pad 110. The electrostatic discharge protection unit 120 serves to protect a gate oxide layer of a transistor in the input buffer unit 130 by discharging the static electricity applied through the pad 110. A detailed description of the structure of the electrostatic discharge protection unit 120 will be omitted for the sake of convenience.

The input buffer unit 130 is configured to buffer the reset signal RESETB applied to the pad 110. The input buffer unit 130 is an inverter including a PMOS transistor P1 and an NMOS transistor N1.

The first inverter INV1 is configured to invert an output signal of the input buffer unit 130. The second inverter INV2 is configured to invert an output signal of the first inverter INV1 and output an internal reset signal RESET_INT to an internal circuit (not illustrated).

Hereinafter, an operation of the integrated circuit 100 will be described with reference to FIGS. 2 to 4.

FIG. 2 is a timing diagram illustrating an operation of the integrated circuit 100 illustrated in FIG. 1. FIGS. 3 and 4 are timing diagrams illustrating the reset signal RESETB of FIG. 2.

Referring to FIG. 2, when a power supply voltage VDD is applied to the integrated circuit, the reset signal RESETB is inputted at a logic high level through the pad 110.

The input buffer unit 130 receives a logic-high reset signal RESETB and outputs a logic-low signal. That is, in response to the logic-high reset signal RESETB, the input buffer unit 130 turns on the NMOS transistor N1 (turns off the PMOS transistor P1) and drives an output terminal to a ground voltage VSS.

The first inverter INV1 inverts the output signal of the input buffer unit 130 and outputs the resulting signal to the second inverter INV2. The second inverter INV2 inverts the output signal of the first inverter INV1 and outputs the internal reset signal RESET_INT. Thus, the output signal RESET_INT of the second inverter INV2 has a logic low level.

In this state, the reset signal RESETB is activated to a logic low level for initialization of the internal circuit. In response to the logic-low reset signal RESETB, the input buffer unit 130 turns on the PMOS transistor P1 and drives the output terminal to a power supply voltage VDD, wherein the NMOS transistor is turned off.

The first inverter INV1 inverts the output signal of the input buffer unit 130 and outputs the resulting signal to the second inverter INV2. The second inverter INV2 inverts the output signal of the first inverter INV1 and outputs the internal reset signal RESET_INT. Thus, the output signal RESET_INT of the second inverter INV2 has a logic high level.

The internal circuit receives the logic-high output signal RESET_INT from the second inverter INV2 and performs an initialization operation. The output signal RESET_INT of the second inverter INV2 is activated for a predetermined time (e.g., 100 ns) to perform a normal initialization operation of the internal circuit.

Meanwhile, the reset signal RESETB applied to the pad 110 is frequently exposed to noise. For example, due to the fabrication state of the pad 110, noise may be carried in the reset signal RESETB applied from the external device through the pad 110.

As illustrated in FIG. 2, the ideal reset signal RESETB maintains a logic high level in a deactivation state and maintains a logic low level in an activation state.

However, as illustrated in FIG. 3, the reset signal RESETB fluctuates due to noise without being targeted to a predetermined level. In a region where a voltage level of the reset signal RESETB is lower than a high voltage level VIH, it may be recognized that the reset signal RESETB is in an activation state, wherein a high voltage level VIH is a reference voltage level used to define a high voltage level. Accordingly, the output signal RESET_INT of the second inverter INV2 is activated to a logic high level. That is, although the reset signal RESETB applied to the pad 110 is in a deactivation state, the reset signal RESETB may be recognized as being in an activation state due to noise and the activated reset signal RESETB may be applied through the input buffer unit 130 to the internal circuit. Thus, this may cause a malfunction due to the unintended initialization of the internal circuit.

On the other hand, as illustrated in FIG. 4, the voltage level of the reset signal RESETB may fluctuate when the reset signal RESETB is in an activation state. In a region where a voltage level of the reset signal RESETB in the activation state becomes higher than a low voltage level VIL in the predetermined time, e.g., 100 ns, it may be recognized that the reset signal RESETB is in a deactivation state. Here the low voltage level VIL is a reference voltage level used to define a logic low level. Accordingly, the output signal RESET_INT of the second inverter INV2 is deactivated to a logic low level. That is, although the reset signal RESETB applied to the pad 110 is in an activation state for an initialization operation of the internal circuit, the reset signal RESETB may be recognized as being in a deactivation state due to noise and the deactivated reset signal RESETB may be applied through the input buffer unit 130 to the internal circuit. In this case, the internal circuit may fail to perform a normal initialization operation. As described above, the reset signal RESETB must maintain an activation state for approximately 100 ns in order to perform a normal initialization operation of the internal circuit.

In order to alleviate the above concerns a known method optimizes the margin of the high voltage level VIH and the margin of the low voltage level VIL. However, the known method has a limitation in that it may affect the yield of a semiconductor memory device.

### SUMMARY OF THE INVENTION

Exemplary embodiments of the present invention are directed to an integrated circuit that is robust against noise and does not degrade the yield of a semiconductor memory device.

In accordance with an exemplary embodiment of the present invention, an integrated circuit includes a pad configured to receive a reset signal from an external device, an input buffer unit configured to buffer a reset signal applied to the pad, and a supplementary driving unit configured to receive an output signal from the input buffer unit and supplementarily drive an input terminal of the input buffer unit to a deactivation level of the reset signal.

In accordance with another exemplary embodiment of the present invention, an integrated circuit includes a pad configured to receive a reset signal from an external device, an input buffer unit configured to buffer a reset signal applied to the pad, a first supplementary driving unit configured to receive an output signal from the input buffer unit and supplementarily drive an input terminal of the input buffer unit to a deactivation level of the reset signal, and a second supplementary driving unit configured to receive the output signal from the input buffer unit and supplementarily drive the input terminal of the input buffer unit to an activation level of the reset signal.

### BRIEF DESCRIPTION OF THE DRAWINGS

FIG. 1 is a block diagram of a known integrated circuit.

FIG. 2 is a timing diagram illustrating an operation of the known integrated circuit illustrated in FIG. 1.

FIGS. 3 and 4 are timing diagrams illustrating the case where noise is carried in a reset signal of FIG. 2.

FIG. 5 is a block diagram of an integrated circuit in accordance with an exemplary embodiment of the present invention.

FIGS. 6 and 7 are timing diagrams illustrating an operation of the integrated circuit illustrated in FIG. 5.

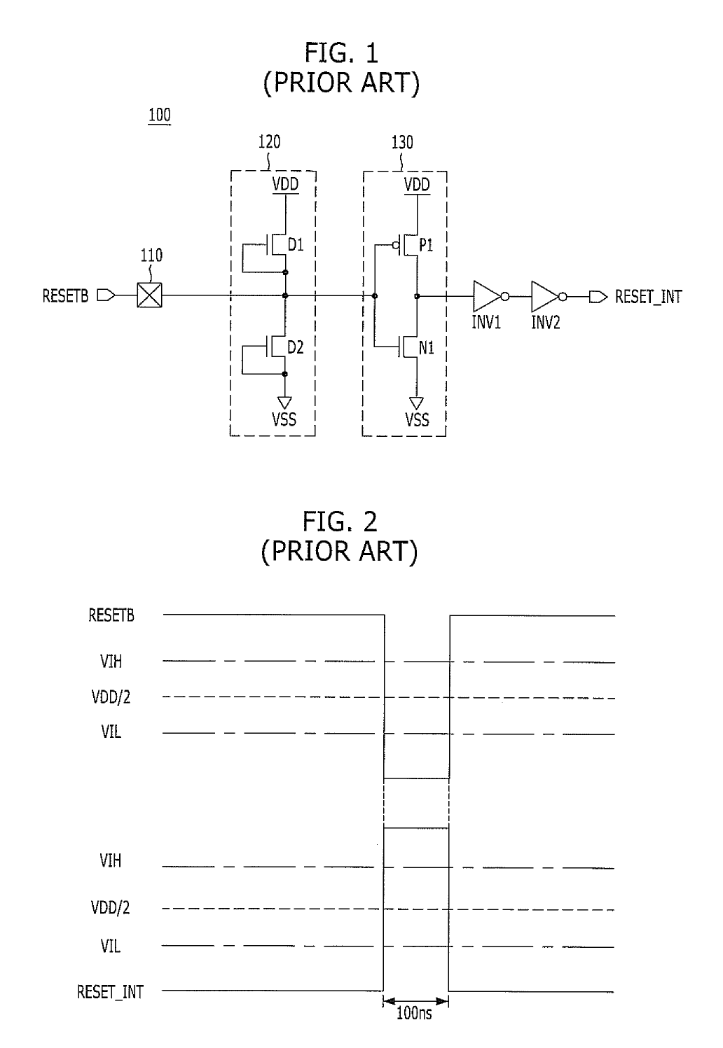

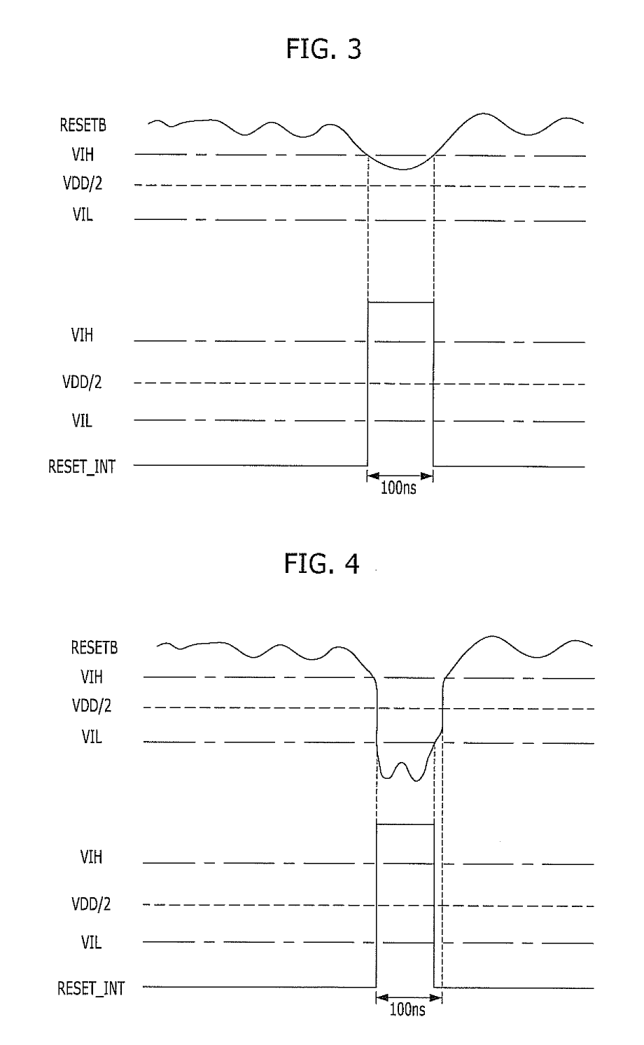

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

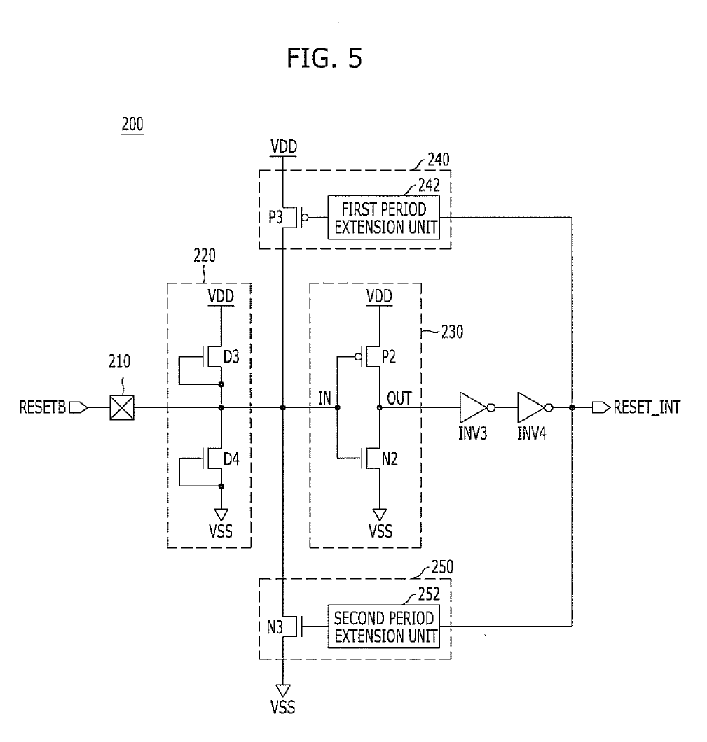

FIG. 5 is a block diagram of an integrated circuit in accordance with an exemplary embodiment of the present invention.

Referring to FIG. 5, an integrated circuit 200 in accordance with an exemplary embodiment of the present invention includes a pad 210, an electrostatic discharge (ESD) protection unit 220, an input buffer unit 230, a first inverter INV3, a second inverter INV4, a first supplementary driving unit 240, and a second supplementary driving unit 250,

The pad 210 is configured to receive a reset signal RESETB from an external device. Typically, the reset signal RESETB is a low active signal. Therefore, the following description will be made on the assumption that the reset signal RESETB is activated to a logic low level.

The electrostatic discharge protection unit 220 is configured to discharge a static electricity of an abnormally high voltage applied to the pad 210. The electrostatic discharge protection unit 220 protects a gate oxide layer of a transistor in the input buffer unit 230 by discharging the static electricity applied through the pad 210. A detailed description of the structure of the electrostatic discharge protection unit 220 will be omitted for the sake of convenience.

The input buffer unit 230 is configured to buffer the reset signal RESETB applied to the pad 210. The input buffer unit 230 is an inverter including a PMOS transistor P2 and an NMOS transistor N2.

The first inverter INV3 is configured to invert an output signal of the input buffer unit 230. The second inverter INV4 is configured to invert an output signal of the first inverter INV3 and output an internal reset signal RESET_INT to an internal circuit (not illustrated).

The first supplementary driving unit 240 is configured to feedback-receive the output signal RESET_INT of the second inverter INV4 and supplementarily drive an input terminal IN of the input buffer unit 230 to a deactivation level of the reset signal RESETB which is in a deactivation state. That is, when the reset signal RESETB inputted to the input buffer unit 230 is at a logic high level, the first supplementary driving unit 240 supplementarily drives the input terminal IN of the input buffer unit 230 to a power supply voltage VDD in order to maintain the current level state of the reset signal RESETB even if noise affects the reset signal RESTB.

The first supplementary driving unit 240 includes a first period extension unit 242 and a PMOS transistor P3. When the output signal RESET_INT of the second inverter INV4 changes from a logic high level to a logic low level, the first period extension unit 242 is configured to extend the logic high level state by a preset period. The PMOS transistor P3 is configured to drive the input terminal IN of the input buffer unit 230 to the power supply voltage VDD in response to the output signal of the first period extension unit 242.

The first period extension unit 242 is configured to extend an enable time of the PMOS transistor P3. For example, the first period extension unit 242 may be implemented using a skew delay. Although the first period extension unit 242 is shown in FIG. 5, it is not necessary to implement this exemplary embodiment of the present invention.

The PMOS transistor P3 has a source connected to a power supply voltage (VDD) terminal, a drain connected to the input terminal IN of the input buffer unit 230, and a gate receiving the output signal of the first period extension unit 242. Herein, the PMOS transistor P3 may be configured to perform a supplementary driving operation using a driving force smaller than an activation level driving force of the reset signal RESETB with respect to the pad 210. That is, the PMOS transistor P3 is configured to have a sufficiently large gate length. This is to prevent it from affecting the voltage level of the reset signal RESETB when the reset signal RESETB changes to an activation state.

The second supplementary driving unit 250 is configured to feedback-receive the output signal of the input buffer unit 230 and supplementarily drive the input terminal IN of the input buffer unit 230 to an activation level of the reset signal RESETB in an activation period of the reset signal RESETB. That is, when the reset signal RESETB inputted to the input buffer unit 230 is at a logic low level, the second supplementary driving unit 250 supplementarily drives the input terminal TN of the input buffer unit 230 to a ground voltage VSS in order to maintain the current level state of the reset signal RESETB even if noise affects the reset signal RESTB.

The second supplementary driving unit 250 includes a second period extension unit 252 and an NMOS transistor N3. When the output signal of the second inverter INV4 changes from a logic low level to a logic high level, the second period extension unit 252 is configured to extend the logic low level state by a preset time. The NMOS transistor N3 is configured to drive the input terminal IN of the input buffer unit 230 to the ground voltage VSS in response to the output signal of the second period extension unit 252.

The second period extension unit 252 is configured to extend an enable time of the NMOS transistor N3. For example, the second period extension unit 252 may be implemented using a skew delay. Although, the second period extension unit 252 is shown in FIG. 5, it is not necessary to implement this exemplary embodiment of the present invention.

The NMOS transistor N3 has a source connected to a ground voltage (VSS) terminal, a drain connected to the input terminal IN of the input buffer unit 230, and a gate receiving the output signal of the second period extension unit 252. Herein, the NMOS transistor N3 may be configured to perform a supplementary driving operation using a driving force smaller than a deactivation level driving force of the reset signal RESETB with respect to the pad 210. That is, the NMOS transistor N3 is configured to have a sufficiently large gate length. This is to prevent it from affecting the voltage level of the reset signal RESETB when the reset signal RESETB changes to a deactivation state.

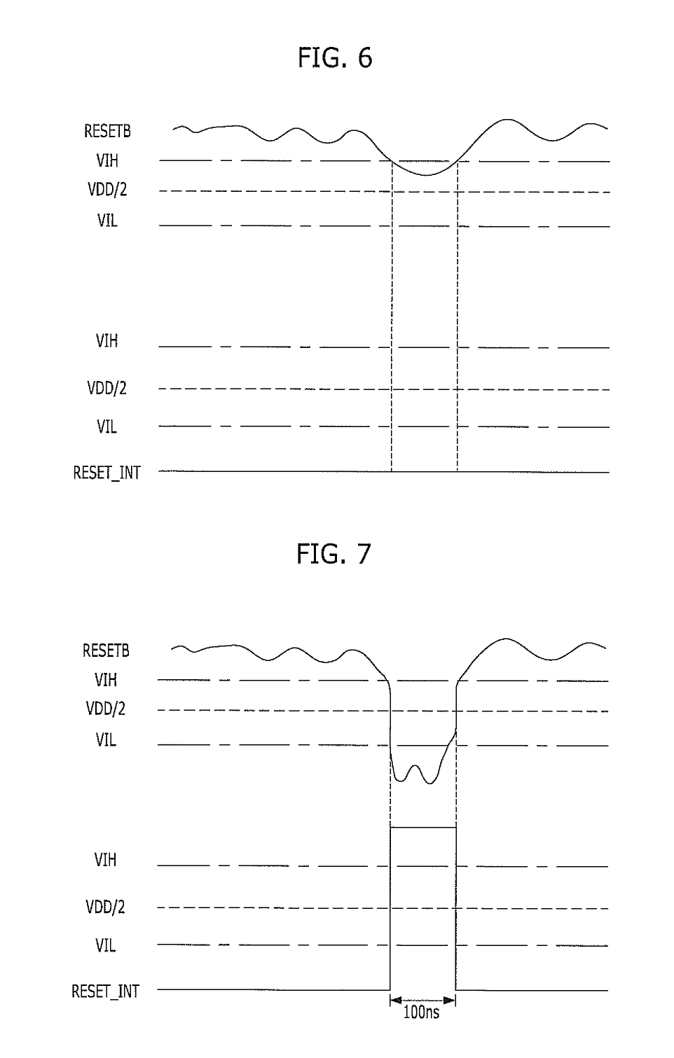

Hereinafter, an operation of the integrated circuit in accordance with an exemplary embodiment of the present invention will be described in more detail with reference to FIGS. 6 and 7.

FIGS. 6 and 7 are timing diagrams illustrating an operation of the integrated circuit 200 illustrated in FIG. 5.

FIG. 6 is a timing diagram illustrating an operation of the case where the reset signal applied to the integrated circuit 200 of FIG. 5 is in a deactivation state.

Referring to FIG. 6, when the power supply voltage VDD is applied to the integrated circuit, the reset signal RESETB is inputted at a logic high level through the pad 210. In an ideal case, the reset signal RESETB inputted through the pad 210 maintains a logic high level in a deactivation state and maintains a logic low level in an activation state. However, the reset signal RESETB fluctuates due to noise without being targeted to a predetermined level. For example, noise may be generated due to a fabrication condition, e.g., a fabrication state of the pad 210, and the noise may be added to the reset signal RESETB applied from an external device through the pad 210.

When the voltage level of the fluctuating reset signal RESETB is higher than a high voltage level VIH, the reset signal RESETB inputted to the input buffer unit 230 maintains a logic high level, wherein the high voltage level VIH is a reference voltage level used to define a logic high level. In this case, the input buffer unit 230 turns on the NMOS transistor N2 and turns off the PMOS transistor P2 to drive the output terminal OUT to the ground voltage VSS.

The first inverter INV3 inverts the output signal of the input buffer unit 230 and outputs the resulting signal to the second inverter INV4. The second inverter INV4 inverts the output signal of the first inverter INV3 and outputs the resulting signal as the output signal RESET_INT to the internal circuit. Thus, the output signal RESET_INT of the second inverter INV4 has a logic low level.

When the output signal RESET_INT of the second inverter INV4 is at a logic low level, the first supplementary driving unit 240 drives the input terminal IN of the input buffer unit 230 to a deactivation level of the reset signal RESETB but the second supplementary driving unit 250 does not operate. That is, the PMOS transistor P3 drives the input terminal IN of the input buffer unit 230 to the power supply voltage VDD in response to the output signal RESET_INT of the second inverter INV4 received through the first period extension unit 242. The NMOS transistor N3 is turned off in response to the output signal RESET_INT of the second inverter INV4 received through the second period extension unit 252.

Meanwhile, due to noise, the voltage level of the reset signal RESETB may become lower than the high voltage level VIH. However, the input terminal IN of the input buffer unit 230 is driven by the first supplementary driving unit 240 to the power supply voltage VDD, thereby compensating the voltage level of the reset signal RESETB. Thus, the reset signal RESETB having a voltage level higher than the high voltage level VIH is inputted to the input buffer unit 230, and the output signal RESET_INT of the second inverter INV4 is maintained at a logic low level.

FIG. 7 is a timing diagram illustrating an operation of the case where the reset signal applied to the integrated circuit 200 of FIG. 5 is in an activation state.

Referring to FIG. 7, when the power supply voltage VDD is applied to the integrated circuit, the reset signal RESETB is inputted at a logic high level through the pad 210. The reset signal RESETB inputted through the pad 210 fluctuates due to noise without being targeted to a predetermined level.

When the voltage level of the fluctuating reset signal RESETB is higher than the high voltage level VIH, the reset signal RESETB inputted to the input buffer unit 230 maintains a logic high level. In this case, the input buffer unit 230 turns on the NMOS transistor N2 and turns off the PMOS transistor P2 to drive the output terminal OUT to the ground voltage VSS.

The first inverter INV3 inverts the output signal of the input buffer unit 230 and outputs the resulting signal to the second inverter INV4. The second inverter INV4 inverts the output signal of the first inverter INV3 and outputs the resulting signal to the internal circuit. Thus, the output signal RESET INT of the second inverter INV4 has a logic low level.

When the output signal RESET_INT of the second inverter INV4 is at a logic low level, the first supplementary driving unit 240 drives the input terminal IN of the input buffer unit 230 to a deactivation level of the reset signal RESETB but the second supplementary driving unit 250 does not operate. That is, the PMOS transistor P3 drives the input terminal IN of the input buffer unit 230 to the power supply voltage VDD in response to the output signal RESET_INT of the second inverter INV4 received through the first period extension unit 242, and the NMOS transistor N3 is turned off in response to the output signal RESET_INT of the second inverter INV4 received through the second period extension unit 252.

In this state, the reset signal RESETB is activated during a predetermined time period for initialization of the internal circuit. For example, the voltage level of the reset signal RESETB changes from a logic high level to a logic low level for a predetermined time, e.g., 100 ns. Herein, the reset signal RESETB fluctuates due to noise without being targeted to a logic low level.

The input buffer unit 230 turns on the PMOS transistor P2 and turns off the NMOS transistor N2 to drive the output terminal OUT to the power supply voltage VDD.

The first inverter INV3 inverts the output signal of the input buffer unit 230 and outputs the resulting signal to the second inverter INV4. The second inverter INV4 inverts the output signal of the first inverter INV3 and outputs the resulting signal as the output signal RESET_INT to the internal circuit. Thus, the output signal RESET_INT of the second inverter INV4 has a logic high level.

When the output signal RESET_INT of the second inverter INV4 is at a logic high level, the first supplementary driving unit 240 stops operating, but the second supplementary driving unit 250 drives the input terminal IN of the input buffer unit 230 to an activation level of the reset signal RESETB. That is, the PMOS transistor P3 is turned off in response to the output signal RESET_INT of the second inverter INV4 received through the first period extension unit 242. The NMOS transistor N3 drives the input terminal IN of the input buffer unit 230 to the ground voltage VSS in response to the output signal RESET_INT of the second inverter INV4 received through the second period extension unit 252.

Accordingly, even when the voltage level of the reset signal RESETB becomes higher than the low voltage level VIL, the second supplementary driving unit 250 drives the input terminal IN of the input buffer unit 230 to the ground voltage VSS and thus the voltage level of the reset signal RESETB can be compensated. Thus, the reset signal RESETB is inputted to the input buffer unit 230 while maintaining the voltage level lower than the low voltage level VIL. Accordingly, the output signal RESET_INT of the second inverter INV4 is at a logic high level for a predetermined time period (e.g., 100 ns), so that the internal circuit may perform a normal initialization operation.

In accordance with the exemplary embodiment of the present invention, the noise added to the reset signal RESETB may be internally disregarded and thus a malfunction due to an unintended initialization operation may be prevented and performance of an intended initialization operation may be secured.

As described above, an integrated circuit in accordance with an exemplary embodiment of the present invention can internally disregard the noise carried in the reset signal, and thus may prevent an unintended initialization operation in the deactivation state of the reset signal so that the circuit may perform a normal initialization operation in the activation state of the reset signal. Accordingly, the stability and the operational reliability of the integrated circuit can be improved, thus improving the yield thereof.

While the present invention has been described with respect to the specific embodiments, it will be apparent to those skilled in the art that various changes and modifications may be made without departing from the spirit and scope of the invention as defined in the following claims.

What is claimed is:

1. An integrated circuit comprising:
a pad configured to receive a reset signal from an external device;
an input buffer unit configured to buffer a reset signal applied to the pad; and
a supplementary driving unit configured to receive an output signal from the input buffer unit and supplementarily drive an input terminal of the input buffer unit to a deactivation level of the reset signal.

2. The integrated circuit of claim 1, wherein the supplementary driving unit supplementarily drives the input terminal of the input buffer unit to a level lower than an activation level of the reset signal.

3. The integrated circuit of claim 2, wherein the supplementary driving unit comprises a PMOS transistor having a source connected to a power supply voltage terminal, a drain connected to the input terminal of the input buffer unit, and a gate configured to receive the output signal from the input buffer unit.

4. The integrated circuit of claim 3, wherein the supplementary driving unit further comprises a first period extension unit configured to extend a deactivated output signal of the input buffer, denoting the deactivation level, by a preset time and provide the extended output signal of the input buffer to the gate of the PMOS transistor, when the output signal of the input buffer unit changes from a deactivation state to an activation state.

5. The integrated circuit of claim 4, wherein the first period extension unit comprises a skew delay.

6. The integrated circuit of claim 1, further comprising a second supplementary driving unit configured to receive the output signal from the input buffer unit and supplementarily drive the input terminal of the input buffer unit to an activation level of the reset signal.

7. The integrated circuit of claim 6, wherein the second supplementary driving unit supplementarily drives the input terminal of the input buffer unit to a level lower than the deactivation level of the reset signal.

8. The integrated circuit of claim 7, wherein the second supplementary driving unit comprises an NMOS transistor having a source connected to a ground voltage terminal, a drain connected to the input terminal of the input buffer unit, and a gate configured to receive the output signal from the input buffer unit.

9. The integrated circuit of claim 8, wherein the second supplementary driving unit further comprises a second period extension unit configured to extend an activated output signal of the input buffer, denoting the activation level, by a preset time and transfer the extended output signal from the input buffer to the gate of the NMOS transistor, when the output signal of the input buffer unit changes from an activation state to a deactivation state.

10. The integrated circuit of claim 9, wherein the second period extension unit comprises a skew delay.

11. An integrated circuit comprising:
a pad configured to receive a reset signal from an external device;
an input buffer unit configured to buffer a reset signal applied to the pad;
a first supplementary driving unit configured to receive an output signal from the input buffer unit and supplementarily drive an input terminal of the input buffer unit to a deactivation level of the reset signal ; and
a second supplementary driving unit configured to receive the output signal from the input buffer unit and supplementarily drive the input terminal of the input buffer unit to an activation level of the reset signal.

12. The integrated circuit of claim 11, wherein the first supplementary driving unit supplementarily drives the input terminal of the input buffer unit to a level lower than the activation level of the reset signal.

13. The integrated circuit of claim 12, wherein the first supplementary driving unit comprises a PMOS transistor having a source connected to a power supply voltage terminal, a drain connected to the input terminal of the input buffer unit, and a gate configured to receive the output signal from the input buffer unit.

14. The integrated circuit of claim 13, wherein the first supplementary driving unit further comprises a first period extension unit configured to extend a deactivated output signal of the input buffer, denoting the deactivation level, by a preset time and transfer the extended deactivated output signal to the gate of the PMOS transistor, when the output signal of the input buffer unit changes from a deactivation state to an activation state.

15. The integrated circuit of claim 14, wherein the first period extension unit comprises a skew delay.

16. The integrated circuit of claim 11, wherein the second supplementary driving unit supplementarily drives the input terminal of the input buffer unit to a level lower than the deactivation level of the reset signal.

17. The integrated circuit of claim 16, wherein the second supplementary driving unit comprises an NMOS transistor having a source connected to a ground voltage terminal, a drain connected to the input terminal of the input buffer unit, and a gate configured to receive the output signal from the input buffer unit.

18. The integrated circuit of claim 17, wherein the second supplementary driving unit further comprises a second period extension unit configured to extend an activated output signal of the input buffer, denoting the activation level, by a preset time and transfer the extended activated output signal to the gate of the NMOS transistor, when the output signal of the input buffer unit changes from an activation state to a deactivation state.

19. The integrated circuit of claim 18, wherein the second period extension unit comprises a skew delay.
